(19) United States
(12) Patent Application Publication
(10) Pub. No.: US 2024/0341117 A1
(43) Pub. Date: Oct. 10, 2024

(54) QUANTUM DOT LIGHT EMITTING DIODE AND MANUFACTURING METHOD THEREOF

(71) Applicant: TCL TECHNOLOGY GROUP CORPORATION, Huizhou (CN)

(72) Inventors: Jin WANG, Huizhou (CN); Yiran YAN, Huizhou (CN); Likuan ZHOU, Huizhou (CN); Yixing YANG, Huizhou (CN); Weiran CAO, Huizhou (CN)

(21) Appl. No.: 18/270,709

(22) PCT Filed: Dec. 29, 2021
(86) PCT No.: PCT/CN2021/142737

§ 371 Date: Oct. 10, 2023

(30) Foreign Application Priority Data
Dec. 31, 2020 (CN) 202011639231.9

(51) Int. Cl. H10K 50/82; H10K 50/115

(52) U.S. Cl. CPC H10K 50/82; H10K 50/115

(57) ABSTRACT

This disclosure discloses a quantum dot light emitting diode and a manufacturing method thereof. The quantum dot light emitting diode includes an anode and a cathode disposed opposite to each other, a quantum dot light-emitting layer disposed between the anode and the cathode, and an electronic functional layer disposed between the quantum dot light-emitting layer and the cathode; a surface of the cathode facing away from the anode is treated with an active material, or a buffer layer is provided on the surface of the cathode facing away from the anode, and material of the buffer layer contains an active material; in this case the active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

This disclosure claims the benefit of Chinese Patent Application No. 202011639231.9, entitled QUANTUM DOT LIGHT EMITTING DIODE AND MANUFACTURING METHOD THEREOF, which was filed with China National Intellectual Property Administration on Dec. 31, 2020, and the entire contents of which are incorporated herein by reference.

### TECHNICAL FIELD

The present disclosure relates to the technical field of display, and more particularly, relates to a quantum dot light emitting diode and manufacturing method thereof.

### BACKGROUND

Quantum dot light emitting diode (QLED) is an electroluminescent device based on quantum dots (QDs) technology and has a series of excellent characteristics such as self-illumination, no need of a backlight module, wide viewing angle, high contrast, being all-solid-state, applicability to a flexible panel, good temperature characteristics, high response speed, being energy-saving and environmental friendly, and the like, and has become a research hotspot and a key development direction of novel display technology.

Although the structure of an organic light-emitting diode (OLED) device has been referred to and used in a QLED device, the two devices have huge differences in aging phenomena and aging mechanism due to the differences in material composition. For example, QLED devices have various efficiencies (current, power, or external quantum efficiency) decreased or increased over time, i.e., “negative aging effect” and “positive aging effect”. At present, the mechanism of the aging effect is not clear, and many research summaries indicate that the device efficiency changes mainly because of factors such as hole functional layer degradation, interface charge aggregation, electron functional layer surface defect state suppression and charge mobility change. In addition, the matching differences between the materials of the quantum dots with different light-emitting colors and the materials of other functional layers also cause different aging mechanisms of the device. For example, the aging effect of red QLED devices is more caused by the degradation of the organic hole functional layer, while the aging effect of blue QLED devices is more caused by the electron aggregation at the electronic functional layer resulted from the mismatch of the conduction-band maximum (CBM) of the quantum dot light-emitting layer and the electronic functional layer.

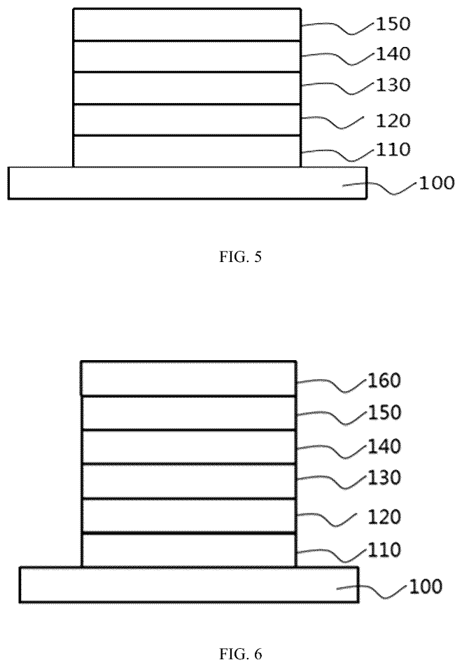

Some Chinese researchers have provided a method and structure for improving the positive aging effect and stability of a quantum dot diode, which discloses: a QLED device packaged by a curable resin containing an active material such as saturated/unsaturated carboxylic acid, the device has a significant positive aging effect, and the packaged device may have the efficiency further improved and have the forward aging process further accelerated after a heat treatment (the positive aging effect is generally completed by about 4-8 days generally, and the efficiency tends to be stable). According to the technical solution, the active material is mixed into the curable encapsulating resin, and the QLED device is exposed to the ambient environment containing the active material or the QLED stacked layers are cleaned with the solution containing the active material to introduce the active material into the QLED device. The data of FIG. 5 of this patent have proved that the positive aging effect of the green QLED device is most significant, in which the efficiency is improved by about 175% (where the efficiency improvement ratio is the percentage of the ratio of the difference between the maximum device efficiency and the first day test efficiency to the first day test efficiency), but the positive aging effects of the blue and red QLED devices are relatively small with the highest efficiency improved by only about 20%.

### SUMMARY

### Technical Problem

One objective of the embodiments of the present disclosure is to provide a quantum dot light emitting diode and manufacturing method thereof.

### Technical Solutions to the Problem

### Technical Solutions

The technical solutions adopted in the embodiments of the present disclosure are as follows:

A first aspect of the embodiments of the present disclosure provides a quantum dot light emitting diode, including an anode and a cathode disposed opposite to each other, a quantum dot light-emitting layer disposed between the anode and the cathode, and an electronic functional layer disposed between the quantum dot light-emitting layer and the cathode;
a surface of the cathode facing away from the anode is treated with an active material, or a buffer layer is provided on the surface of the cathode facing away from the anode, and material of the buffer layer contains an active material;
in this case the active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.

In some embodiments, in case where the cathode is a cathode whose surface facing away from the anode is treated with the active material, the active material on the surface of the cathode is 0.001%-1% of the total weight of the cathode.

In some embodiments, in case where the buffer layer is provided on the surface of the cathode facing away from the anode, the material of the buffer layer is a mixed material of the active material and a polymer.

In some embodiments, the polymer is selected from one or more of polymethyl methacrylate, polyvinyl chloride, poly α-methylstyrene resin, polybutylene terephthalate, polypropylene carbonate, polystyrene, polyhydroxyethyl methacrylate, ethyl polymethacrylate, ethyl polyacrylate, n-butyl polyacrylate, lauryl acrylate, and urethane acrylate.

In some embodiments, a weight percentage of the active ingredient in the buffer layer is 1%-70%.

In some embodiments, thickness of the buffer layer is 100 nm-20 μm.

In some embodiments, treatment with the active material includes: cleaning the cathode with the active material solution; or
preparing a mixed solution containing the active material, depositing the mixed solution on the surface of the cathode; or
exposing the cathode to an atmosphere containing a gaseous active material.

In some embodiments, the buffer layer covers peripheral wall surfaces of the anode, the cathode, the quantum dot light-emitting layer, and the electronic functional layer. A second aspect provides a manufacturing method of quantum dot light emitting diode.

A first manufacturing method of quantum dot light emitting diode includes steps of:
providing a prefabricated device, which includes an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer; and
cleaning the cathode with an active material solution, and preparing the quantum dot light emitting diode; the active material in the active material solution is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In some embodiments, a volume percentage content of the active material in the active material solution is 0.1%-100%.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.

A second manufacturing method of quantum dot light emitting diode includes steps of:
providing a prefabricated device, which includes an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer; and
placing the prefabricated device in an atmosphere environment containing a gaseous active material, treating the cathode with the active material and preparing the quantum dot light emitting diode; the gaseous active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In some embodiments, the atmosphere environment is a mixed gaseous environment of the gaseous active material with at least one of gases such as oxygen, nitrogen, argon, and carbon dioxide.

In some embodiments, the gaseous active material is 1%-50% of total volume of the gases in the atmosphere environment.

In some embodiments, temperature of the gaseous environment is 25-150° C., and total pressure is −0.1-4 MPa.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.

A third manufacturing method of quantum dot light emitting diode includes steps of:
providing a prefabricated device, which includes an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer; and
preparing a mixed solution containing an active material and a polymer, depositing the mixed solution on a surface of the cathode facing away from the anode, annealing, and preparing a buffer layer; the active material in the active material solution is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In some embodiments, the active material is 1%-70% of total weight of the active material and the polymer in the mixed solution.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.

### Benefits of This Disclosure

### Benefits

The quantum dot light emitting diode provided by the embodiments of the present disclosure has the following beneficial effects: the surface of the cathode is treated with the active material, or the buffer layer disposed on the surface of the cathode facing away from the anode contains the active material, and the active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone. After the above treatment, the active material can directly act on the cathode the uncovered surface of the electron functional layer facing away from the quantum dot light-emitting layer, or act on the interface between the cathode and the electronic functional layer through edge permeation. The carboxylic acid, the delocalized pi bond and/or the H+ contained in the active material passivates the defect states, which are distributed on the thin film of the electronic functional material as dispersed nanoscale clusters, by way of coordination and/or H+ reactions and etc., thereby effectively inhibiting the quenching of the surface excitons and increasing the probability of exciton radiation recombination. At the same time, after the active material is introduced into the electronic functional layer or an adjacent interface of the electronic functional layer, the contained carboxylic acid, delocalized pi bond and/or H+ has a modification effect on the material of the electronic functional layer itself, the electronic functional layer/electrode interface, which realizes regulating the electron injection barrier of the electronic functional layer, blocking or promoting electron injection, and facilitates charge injection balance. In prior art, the positive aging effect efficiency of blue and red QLED devices is improved by 20% at most, while the positive aging effect efficiency of blue and red quantum dot light emitting diodes provided by the present disclosure has been respectively improved by 213.6% and 160.5% at most 6 days later, and the positive aging effect of the devices is significantly improved.

The manufacturing method of quantum dot light emitting diode provided by the embodiments of the present disclosure has the following beneficial effects: the active material is used to treat the surface of the cathode or arrange the buffer layer containing the active material on the surface of the cathode facing away from the anode, so that the surface of the electronic functional layer and the interface between the electronic functional layer and the cathode are modified, the surface defects of the electronic functional layer and the adjacent interface are modified/passivated, the quenching of the surface exciton is inhibited, the charge aggregation on the electronic functional layer is reduced, and the exciton radiation recombination probability is increased; the electron injection barrier of the electronic functional layer is regulated, which is beneficial to charge injection balance, thereby significantly improving the positive aging effect of the device.

### BRIEF DESCRIPTION OF THE DRAWINGS

### Description of the Drawings

To more clearly illustrate the technical solutions in the embodiments of the disclosure, the figures to be referenced in the description of the embodiments or prior art will be briefly described in the following. Apparently, the described figures are merely some of the embodiments of the present disclosure, and it is possible for those skilled in the art to obtain other figures on the basis of these figures without paying creative labor.

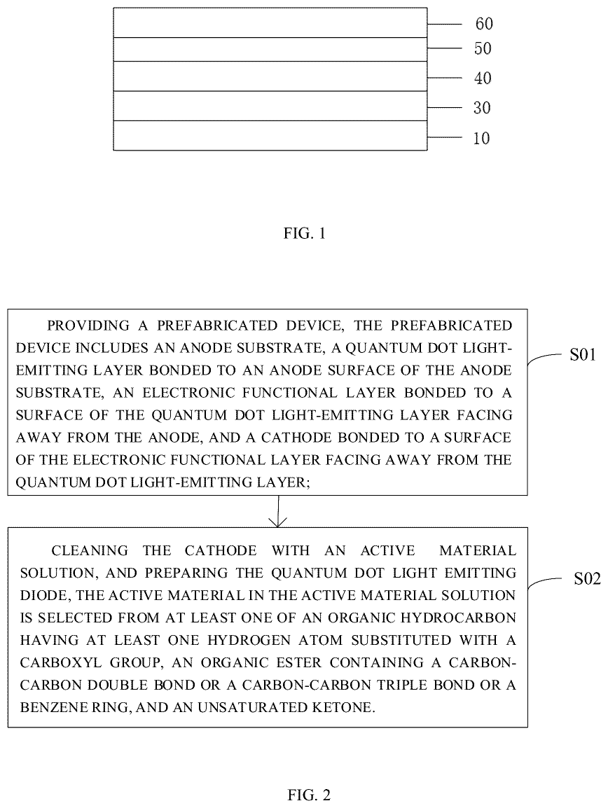

FIG. 1 is a schematic structure diagram of a quantum dot light emitting diode provided in the embodiments of this disclosure;

FIG. 2 is a flow chart of a first manufacturing process of a quantum dot light emitting diode provided in the embodiments of this disclosure;

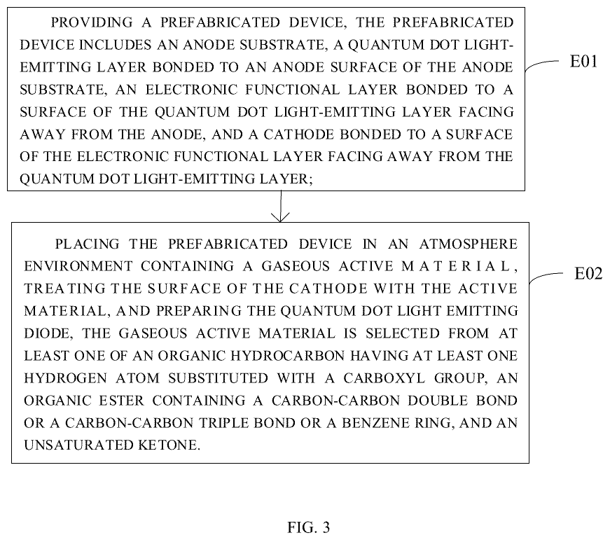

FIG. 3 is a flow chart of a second manufacturing process of a quantum dot light emitting diode provided in the embodiments of this disclosure;

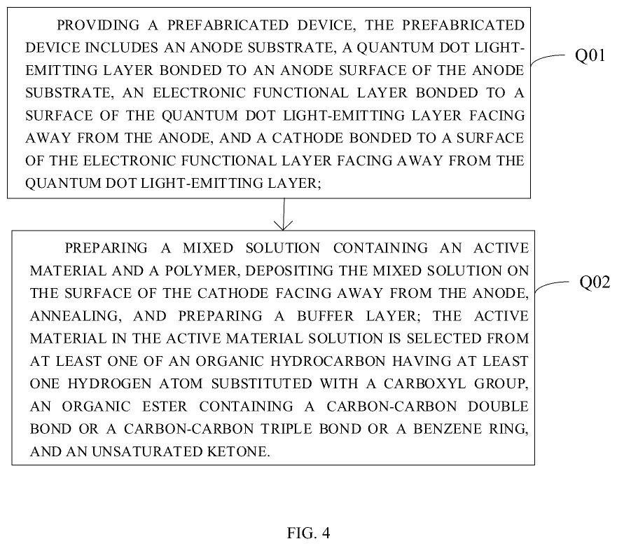

FIG. 4 is a flow chart of a third manufacturing process of a quantum dot light emitting diode provided in the embodiments of this disclosure;

FIG. 5 is a schematic structure diagram of the quantum dot light emitting diode provided in the first, second, fourth and fifth embodiments of this disclosure;

FIG. 6 is a schematic structure diagram of the quantum dot light emitting diode provided in the third, sixth embodiments of this disclosure.

### DETAILED DESCRIPTION OF THE EMBODIMENTS

### The Embodiments of This Disclosure

In order to make the technical problems to be solved by this disclosure, technical solutions, and beneficial effects clearer, this disclosure is further described in detail below with reference to the embodiments. It should be understood that the specific embodiments described herein are merely used to explain this disclosure, and are not intended to limit this disclosure.

In the claims and specific embodiments of this disclosure, the term “and/or” describes an association relationship of associated objects, and indicates three possible relationships. For example, A and/or B may indicate three situations, where A exists alone, both A and B exist at the same time, and B exists alone. In this case, A, B may be singular or plural. The character “/” generally indicates that the associated objects before and after it are in an “or” relationship.

In this disclosure, “at least one” means one or more, and “a plurality of” means two or more. “At least one of the following items”, or the like, refers to any combination of these items, including any combination of a single item (one) or a plurality of items (ones). For example, “at least one (item) of a, b, or c”, or “at least one (item) of a, b, and c” may both represent: a, b, c, a-b (i.e., a and b), a-c, b-c, or a-b-c, where a, b, and c may be singular or plural.

It should be understood that, in various embodiments of this disclosure, the serial numbers of the above processes do not indicate the execution order. Some or all of the steps may be executed in parallel or executed in sequence. The execution order of the respective processes should be determined by the function and internal logic thereof, and should not constitute any limitation on the implementation process of the embodiments of this disclosure.

The terms used in the embodiments of this disclosure are for the purpose of describing particular embodiments only and are not intended to be limiting this disclosure. As used in the embodiments of this disclosure and the appended claims, the singular forms “a”, “said” and “the” are also intended to include the plural forms unless indicated otherwise in the contexts.

The terms “first” and “second” are used for descriptive purposes only and are used to distinguish targets, such as substances, interfaces, messages, requests, and terminals from each other, and cannot be understood as indicating or implying relative importance or implicitly indicating the number of technical features indicated. For example, without departing from the scope of the embodiments of this disclosure, the first XX may also be referred to as the second XX, similarly, the second XX may also be referred to as the first XX. Therefore, the feature defined with “first” and “second” may explicitly or implicitly include one or more of the features.

The weight of the related compositions mentioned in the embodiments of the disclosure may not only refer to the specific content of each composition, but may also represent the proportional relationship between the weights among the compositions. Therefore, all contents fall into the scope of the disclosure of the description of the embodiments of the disclosure, as long as they are scaled up or down according to the contents of the related compositions in the description of the embodiments of this disclosure. Specifically, the mass in the description of the embodiments of the disclosure may use mass units commonly known in chemical fields such as μg, mg, g, kg.

As shown in FIG. 1, a first aspect of the embodiments of this disclosure provides a quantum dot light emitting diode, including an anode 10 and a cathode 50 disposed opposite to each other, a quantum dot light-emitting layer 30 disposed between the anode 10 and the cathode 50, and an electronic functional layer 40 disposed between the quantum dot light-emitting layer 30 and the cathode 50.

The surface of the cathode 50 facing away from the anode 10 is treated with an active material, or a buffer layer 60 is provided on the surface of the cathode 50 facing away from the anode 10, and the material of the buffer layer 60 contains an active material.

The active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In the quantum light emitting diode provided in the embodiments of this disclosure, the surface of the cathode 50 is treated with an active material, or the buffer layer 60 disposed on the surface of the cathode 50 facing away from the anode 10 contains an active material, and the active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone. After the above treatment, the active material can directly act on the cathode 50 the uncovered surface of the electron functional layer 40 facing away from the quantum dot light-emitting layer 30, or act on the interface between the cathode 50 and the electronic functional layer 40 through edge permeation. The carboxylic acid, the delocalized pi bond and/or the H+ contained in the active material passivates the defect states, which are distributed on the thin film of the electronic functional material as dispersed nanoscale clusters, by way of coordination and/or H+ reactions and etc., thereby effectively inhibiting the quenching of the surface excitons and increasing the probability of exciton radiation recombination. At the same time, after the active material is introduced into the electronic functional layer 40 or an adjacent interface of the electronic functional layer 40, the contained carboxylic acid, delocalized pi bond and/or H+ has a modification effect on the material of the electronic functional layer 40 itself, the electronic functional layer 40/electrode interface, thereby regulating the electron injection barrier of the electronic functional layer 40, blocking or promoting electron injection, and facilitating charge injection balance.

In a manufacturing method of the quantum dot light emitting diode provided by the disclosure, the surface of the cathode 50 is treated with the active material, or the buffer layer 60 containing the active material is provided on the surface of the cathode 50 facing away from the anode 10, so that the surface of the electronic functional layer 40 and the interface between the electronic functional layer and the cathode 50 are modified, the surface defects of the electronic functional layer 40 and the adjacent interface are modified/passivated, the quenching of the surface exciton is inhibited, the charge aggregation on the electronic functional layer 40 is reduced, the exciton radiation recombination probability is increased; and the electron injection barrier of the electronic functional layer 40 is regulated, which is beneficial to charge injection balance, thereby significantly improving the positive aging effect of the device. In addition, the buffer layer 60 may also increase the water and oxygen barrier performance of the device, improve the surface flatness of the device, and provide favorable conditions for a subsequent packaging process.

In the embodiments of this disclosure, the active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone. Specifically, the organic hydrocarbon having at least one hydrogen atom substituted with a carboxyl group refers to a saturated or unsaturated organic carboxylic acid, and the organic carboxylic acid does not contain other active functional group than the carboxylic acid, the carbon-carbon double bond, the carbon-carbon triple bond, and the aromatic ring.

In some embodiments, the organic hydrocarbon having at least one hydrogen atom substituted includes but is not limited to: acetic acid, propionic acid, butyric acid, isobutyric acid, acrylic acid, benzoic acid, methacrylic acid, 3-butenoic acid, crotonic acid; the organic ester containing a carbon-carbon double bond or a carbon-carbon triple bond or a benzene ring includes but is not limited to: hydroxyethyl methacrylate, methyl methacrylate, butyl acrylate, and trimethylolpropane trienate, and the unsaturated ketone includes but is not limited to N-vinyl pyrrolidone.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone. Since these active materials have the carboxylic acid, the delocalized pi bond and/or the H+, it is possible to modify the surface of the electronic functional layer 40 and the interface between the electronic functional layer 40 and the cathode 50 by way of coordination and/or H+ reaction and etc., and the surface defects of the electronic functional layer 40 and the adjacent interface are modified/passivated, the quenching of the surface exciton is inhibited, and the charge aggregation on the electronic functional layer 40 is reduced. And the electron injection barrier of the electronic functional layer 40 is regulated to facilitate charge injection balance, thereby significantly improving the positive aging effect of the device.

The above embodiments of this disclosure are divided into two cases according to the position of the active material in the quantum dot light emitting diode.

In first type of embodiments, the quantum dot light emitting diode includes the anode 10 and the cathode 50 disposed opposite to each other, the quantum dot light emitting layer 30 disposed between the anode 10 and the cathode 50, and the electronic functional layer 40 disposed between the quantum dot light emitting layer 30 and the cathode 50. In this case, the surface of the cathode 50 facing away from the anode 10 is treated with the active material.

In some embodiments, the active material remaining on the surface of the cathode 50 is 0.001%-1% of the total weight of the cathode 50.

In the second type of embodiments, the quantum dot light emitting diode includes the anode 10 and the cathode 50 disposed opposite to each other, the quantum dot light emitting layer 30 disposed between the anode 10 and the cathode 50, the electronic function layer 40 disposed between the quantum dot light emitting layer 30 and the cathode 50, and the buffer layer 60 disposed on the surface of the cathode 50 facing away from the anode 10. In this case, the material of the buffer layer 60 includes an interface layer between the active material and the quantum dot light emitting layer 30.

In some embodiments, the material of the buffer layer 60 is a mixed material of the active material and the polymer. That is, the interface layer is an organic thin film formed by the active material and the polymer. The polymer is used as a carrier, which has stable chemical properties and a certain water and oxygen barrier capability, improves the surface flatness of the device, and provides favorable conditions for the subsequent packaging process. In some embodiments, the polymer may be one or more of polymethyl methacrylate, polyvinyl chloride, poly α-methylstyrene resin, polybutylene terephthalate, polypropylene carbonate, polystyrene, polyhydroxyethyl methacrylate, ethyl polymethacrylate, ethyl polyacrylate, n-butyl polyacrylate, lauryl acrylate, and urethane acrylate.

In some embodiments, the weight percentage of the active ingredient in the buffer layer 60 is 1%-70%. In case where the content of the active material is too low; the positive aging effect is not obvious, but in case where too much active material exists, the positive aging effect is weakened, and even the negative aging effect is resulted. In some embodiments, the thickness of the buffer layer 60 is 100 nm-20 μm. In case where the thickness of the buffer layer 60 is too thick, the overall lightness and thinness and optical performance of the device are affected. In case where the thickness of the buffer layer 60 is too thin, the device is not significantly affected, but the consistency of the thickness of the thin film has high requirements on the manufacturing process.

In some embodiments, the buffer layer 60 covers the peripheral wall surfaces of the anode 10, the cathode 50, the quantum dot light-emitting layer 30, and the electronic functional layer 40 to achieve good water and oxygen barrier performance. It should be understood that in case where other functional layer is further provided between the anode 10 and the cathode 50, the buffer layer 60 also covers the sidewalls of the other functional layer.

On the basis of the above embodiments, the electronic functional layer 40 includes at least one of an electron injection layer and an electron transport layer.

In some embodiments, the quantum dot light emitting diode further includes a hole functional layer disposed between the anode 10 and the quantum dot light emitting layer 30. The hole functional layer includes at least one of a hole transport layer, a hole injection layer, and an electron blocking layer.

In the embodiments of this disclosure, the quantum dot light emitting diode may further include a substrate, and the anode 10 is disposed on the substrate. That is, the quantum dot light emitting diode is a positive quantum dot light emitting diode.

In the above embodiments, the substrate may include a conventional rigid substrate such as a glass, a metal foil, etc., or a flexible substrate such as polyimide (PI), polycarbonate (PC), polystyrene (PS), polyethylene (PE), polyvinyl chloride (PV), polyvinylpyrrolidone (PVP), polyethylene terephthalate (PET), or the like, which is mainly for supporting.

The anode 10 may adopt common anode material and thickness, which is not limited in the embodiments of this disclosure. For example, the anode material may be indium tin oxide (ITO), indium zinc oxide (IZO) conductive glass or indium tin oxide, indium zinc oxide electrode, or other metal materials such as gold, silver, aluminum, etc. In some embodiments, the anode 10 is an ITO electrode. In this case, the hole injection layer including a two-dimensional black phosphorus material and a metal compound has a high work function, and has a high degree of matching with the anode 10; and can perform excellent carrier mobility, and replace PEDOT: PSS without damaging the anode 10.

In the embodiments of this disclosure, the quantum dot nanoparticle material is one or more of II-VI semiconductor nanocrystals, III-V semiconductor nanocrystals, II-V semiconductor nanocrystals, III-VI semiconductor nanocrystals, IV-VI semiconductor nanocrystals, I-III-VI semiconductor nanocrystals, I-III-VI core-shell structure quantum dots, II-IV-VI semiconductor nanocrystals, II-IV-VI core-shell structure quantum dots, or group IV elementary substances. The quantum dot nanoparticle material may be a red-light quantum dot, and correspondingly, the quantum dot light emitting diode is a red-light quantum dot light emitting diode; the quantum dot nanoparticle material may be a blue-light quantum dot, and correspondingly, the quantum dot light emitting diode is a blue-light quantum dot light emitting diode; and the quantum dot nanoparticle material may be a green-light quantum dot, and correspondingly, the quantum dot light emitting diode is a green-light quantum dot light emitting diode.

In the embodiments of this disclosure, the electronic functional layer 40 includes at least one of an electron transport layer and an electron injection layer. The material of the electronic functional layer 40 is selected from inorganic materials having electron transport capability, in particular inorganic nanoparticle materials, including one or more of doped or non-doped metal oxide. In some embodiments, the material of the electronic functional layer 40 is selected from one or more of ZnO, TiO₂, SnO₂, Ta₂O₃, ZrO₂, NiO, TiLiO, ZnAlO, ZnMgO, ZnSnO, ZnLiO, InSnO.

In the embodiments of this disclosure, the cathode 50 may be a common cathode material, including but not limited to one or more of a metal material, a carbon material, and a metal oxide. The metal material includes one or more of Al, Ag, Cu, Mo, Au, Ba, Ca, and Mg; the carbon material includes one or more of graphite, carbon nanotubes, graphene, and carbon fibers; the metal oxide may be a doped or non-doped metal oxide including one or more of ITO, FTO, ATO, AZO, GZO, IZO, MZO, and AMO.

In case where the quantum dot light emitting diode is a blue-light quantum dot light emitting diode or a red-light quantum dot light emitting diode, after the active material is introduced into the quantum dot light emitting layer 30, the positive aging effect of the device is more significant.

In some embodiments, the treatment with the active material includes cleaning the cathode 50 with the active material solution, or preparing a mixed solution containing the active material, depositing the mixed solution on the surface, or exposing the cathode 50 to an atmosphere containing a gaseous active material. Please refer to the following manufacturing method for the details.

The quantum dot light emitting diode provided by the present disclosure may be manufactured by the following method.

A second aspect of the embodiments of this disclosure provides three manufacturing methods of quantum dot light emitting diode.

As shown in FIG. 2, the first manufacturing method of quantum dot light emitting diode includes the following steps:

A quantum dot light emitting diode, includes the following steps:
S01: providing a prefabricated device, the prefabricated device includes an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer;
S02: cleaning the cathode with an active material solution, and preparing the quantum dot light emitting diode after treating the surface of the cathode with the active material, the active material in the active material solution is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In the above step S01, the prefabricated device includes the anode substrate, the quantum dot light-emitting layer coupled to the anode surface of the anode substrate, the electronic functional layer coupled to the surface of the quantum dot light-emitting layer facing away from the anode, and the cathode coupled to the surface of the electronic functional layer facing away from the quantum dot light-emitting layer. The selection of the material of each layer is as described above and will not be repeated here.

In the above step S02, the active material solution is used to provide the active material, so that the active material treats and is remained on the surface of the cathode in the process of cleaning the cathode. The selection of the active material is as described above and will not be repeated here.

In some embodiments, the volume percentage content of the active material in the active material solution is 0.1%-100%.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone. In some embodiments, the active material is acrylic acid.

As shown in FIG. 3, the second manufacturing method of quantum dot light emitting diode includes the following steps:
E01: providing a prefabricated device, the prefabricated device includes an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer;
E02. placing the prefabricated device in an atmosphere environment containing a gaseous active material to prepare the quantum dot light emitting diode, the gaseous active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In the above step E01, the prefabricated device includes the anode substrate, the quantum dot light-emitting layer coupled to the anode surface of the anode substrate, the electronic functional layer coupled to the surface of the quantum dot light-emitting layer facing away from the anode, and the cathode coupled to the surface of the electronic functional layer facing away from the quantum dot light-emitting layer. The selection of the material of each layer is as described above and will not be repeated here.

In the above step E02, the prefabricated device is placed in the atmosphere environment containing the gaseous active material, so that the prefabricated device, especially the cathode, is exposed to the environment containing the gaseous active material, so that the surface of the cathode facing away from the anode is treated with the active material. The atmosphere environment containing the gaseous active material may be an atmosphere environment of the pure gaseous active material; or may be an inert atmosphere environment containing the gaseous active material. The inert atmosphere includes a nitrogen atmosphere or an argon atmosphere. In some embodiments, the atmosphere environment is a mixed gaseous environment of the gaseous active material with at least one of gases such as oxygen, nitrogen, argon, and carbon dioxide. In some embodiments, the gaseous active material is 1%-50% of the total volume of the gases in the atmosphere environment; in some embodiments, the temperature of the gaseous environment is 25-150° C., and the total pressure is −0.1-4 MPa.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone. In some embodiments, the active material is acrylic acid.

As shown in FIG. 4, the third manufacturing method of quantum dot light emitting diode includes the following steps:
Q01. providing a prefabricated device, the prefabricated device includes an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer;
Q02. preparing a mixed solution containing an active material and a polymer, depositing the mixed solution on the surface of the cathode facing away from the anode, annealing, and preparing a buffer layer; the active material in the active material solution is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

In the above step Q01, the prefabricated device includes the anode substrate, the quantum dot light-emitting layer coupled to the anode surface of the anode substrate, the electronic functional layer coupled to the surface of the quantum dot light-emitting layer facing away from the anode, and the cathode coupled to the surface of the electronic functional layer facing away from the quantum dot light-emitting layer. The selection of the material of each layer is as described above and will not be repeated here.

In the above step Q02, in some embodiments, the total weight of the active material and the polymer is 1%-70% of the mixed solution.

In some embodiments, the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone. In some embodiments, the active material is acrylic acid.

Further, a mixed solution is deposited on the surface of the cathode facing away from the anode, and dried to prepare the organic buffer layer containing the active material.

According to the manufacturing method of quantum dot light emitting diode provided by the embodiments of the present disclosure, the active material is used to treat the surface of the cathode or arrange the buffer layer, so that the resulted quantum dot light emitting diode may reduce the charge aggregation on the electronic functional layer, passivate the surface defects, and significantly improve the positive aging effect of the device.

The following describes with specific embodiments.

### Embodiment 1

FIG. 5 shows a red quantum dot light emitting diode with a substrate 100, an anode 110 located on the substrate 100, and sequentially stacked hole function layer 120, quantum dot light-emitting layer 130, electronic function layer 140, and cathode 150, in which the material of the substrate 100 is silicon glass, the material of the anode 110 is ITO, the material of the hole function layer 120 is TFB, the material of the quantum dot light-emitting layer 130 is CdZnSe/ZnSe/Zns, the material of the electronic function layer 140 is ZnO, the material of the cathode 150 is Ag, and the surface of the cathode facing away from the anode is treated with acrylic acid.

A manufacturing method of quantum dot light emitting diode includes:
spin coating a hole functional material on the anode substrate to prepare the hole functional layer 120, and preparing the quantum dot light-emitting layer 130 on the hole functional layer 120;
spin coating an electronic functional material on the surface of the quantum dot light-emitting layer 130 to prepare the electronic functional layer 140;
evaporation depositing the cathode 150 on the surface of the electronic functional layer 140 to obtain a prefabricated device;
cleaning the cathode 150 of the prefabricated device with an acrylic acid solution having a concentration of 30%, and treating the surface of the cathode 150 with acrylic acid.

### Embodiment 2

A red quantum dot light emitting diode, which has same composition and materials as those of Embodiment 1, differs in the manner of “treating the surface of the cathode 150 with acrylic acid”. Specifically, the manner of “treating the surface of the cathode 150 with acrylic acid” in Embodiment 2 is as follows:
placing the obtained prefabricated device in an atmosphere composed of N₂ or Ar and acrylic vapor for treatment for 20 minutes, and treating the surface of the cathode 150 with acrylic acid, the volume of the acrylic acid is 30% of the total volume of the gases; the temperature of the gaseous environment is 80° C., and the total pressure is 1 MPa.

### Embodiment 3

FIG. 6 shows a red quantum dot light emitting diode with a substrate 100, an anode 110 located on the substrate 100, and sequentially stacked hole function layer 120, quantum dot light-emitting layer 130, electronic function layer 140, cathode 150, and buffer layer 160, in which the material of the substrate 100 is silicon glass, the material of the anode 110 is ITO, the material of the hole function layer 120 is TFB, the material of the quantum dot light-emitting layer 130 is CdZnSe/ZnSe/Zns, the material of the electronic function layer 140 is ZnO, the material of the cathode 150 is Ag, and the material of the buffer layer is a mixture of acrylic acid and polymethyl methacrylate.

A manufacturing method of quantum dot light emitting diode includes:
spin coating a hole functional material on the anode substrate to prepare the hole functional layer 120, and preparing the quantum dot light-emitting layer 130 on the hole functional layer 120;
spin coating an electronic functional material on the surface of the quantum dot light-emitting layer 130 to prepare the electronic functional layer 140;
evaporation depositing the cathode 150 on the surface of the electronic functional layer 140 to obtain a prefabricated device;
preparing a mixed solution of acrylic acid and polymethyl methacrylate, in which the acrylic acid is 20% of the total weight of the acrylic acid and the polymethyl methacrylate;
depositing the mixed solution on the surface of the cathode 150 to prepare the buffer layer having a thickness of 5 μm.

The current efficiency (cd/A) of the red quantum dot light-emitting diodes prepared in Embodiments 1-3 is tested, and the test method is as follows: scanning from 0V to 7V at a step of 0.2 V, and respectively monitoring the current (A) and the brightness (nit/m²) by using the GIB source table and the integrating sphere to obtain the current efficiency test values.

The test results are shown in Table 1 below.

TABLE 1

| current efficiency (cd/A) | 1 day later | 3 days later | 6 days later |
|---|---|---|---|
| Embodiment 1 | 7.3 | 11.6 | 15.7 |
| Embodiment 2 | 7.9 | 10.8 | 14.9 |
| Embodiment 3 | 9.3 | 15.7 | 24.2 |

It can be seen from Table 1 that compared with the current efficiency of the first day, the current efficiency of the red quantum dot light emitting diode provided in Embodiment 1 is improved by 115% 6 days later; the current efficiency of the red quantum dot light emitting diode provided in Embodiment 2 is improved by 89.2% 6 days later; and the current efficiency of the red quantum dot light emitting diode provided in Embodiment 3 is improved by 160.5% 6 days later. It can be seen that the positive aging efficiency of the red quantum dot light emitting diodes provided by the embodiments of the present disclosure is significantly improved.

### Embodiment 4

FIG. 5 shows a blue quantum dot light emitting diode with a substrate 100, an anode 110 located on the substrate 100, and sequentially stacked hole functional layer 120, quantum dot light-emitting layer 130, electronic functional layer 140, and cathode 150, in which the material of the substrate 100 is silicon glass, the material of the anode 110 is ITO, the material of the hole functional layer 120 is TFB, the material of the quantum dot light-emitting layer 130 is CdZnSe/ZnS, the material of the electronic functional layer 140 is ZnO, the material of the cathode 150 is Ag, and the surface of the cathode facing away from the anode is treated with acrylic acid.

A manufacturing method of quantum dot light emitting diode includes:
spin coating a hole functional material on the anode substrate to prepare the hole functional layer 120, and preparing the quantum dot light-emitting layer 130 on the hole functional layer 120;
spin coating an electronic functional material on the surface of the quantum dot light-emitting layer 130 to prepare the electronic functional layer 140;
evaporation depositing the cathode 150 on the surface of the electronic functional layer 140 to obtain a prefabricated device;
cleaning the cathode 150 of the prefabricated device with an acrylic acid solution having a concentration of 30%, and treating the surface of the cathode 150 with acrylic acid.

### Embodiment 5

A blue quantum dot light emitting diode, which has same composition and materials as those of Embodiment 4, differs in the manner of “treating the surface of the cathode 150 with acrylic acid”. Specifically, the manner of “treating the surface of the cathode 150 with acrylic acid” in Embodiment 2 is as follows:

Placing the obtained prefabricated device in an atmosphere composed of N₂ or Ar and acrylic vapor for treatment for 20 minutes, and treating the surface of the cathode 150 with acrylic acid, the volume of the acrylic acid is 30% of the total volume of the gases; the temperature of the gaseous environment is 100° C., and the total pressure is 1 MPa.

### Embodiment 6

FIG. 6 shows a blue quantum dot light emitting diode with a substrate 100, an anode 110 located on the substrate 100, and sequentially stacked hole functional layer 120, quantum dot light-emitting layer 130, electronic functional layer 140, cathode 150, and buffer layer 160, in which the material of the substrate 100 is silicon glass, the material of the anode 110 is ITO, the material of the hole functional layer 120 is TFB, the material of the quantum dot light-emitting layer 130 is CdZnSe/ZnS, the material of the electronic functional layer 140 is ZnO, the material of the cathode 150 is Ag, and the material of the buffer layer is a mixture of acrylic acid and polymethyl methacrylate.

A manufacturing method of quantum dot light emitting diode includes:
spin coating a hole functional material on the anode substrate to prepare the hole functional layer 120, and preparing the quantum dot light-emitting layer 130 on the hole functional layer 120;
spin coating an electronic functional material on the surface of the quantum dot light-emitting layer 130 to prepare the electronic functional layer 140;
evaporation depositing the cathode 150 on the surface of the electronic functional layer 140 to obtain a prefabricated device;
preparing a mixed solution of acrylic acid and polymethyl methacrylate, in which the acrylic acid is 20% of the total weight of the acrylic acid and the polymethyl methacrylate;
depositing the mixed solution on the surface of the cathode 150 to prepare the buffer layer having a thickness of 5 μm.

The current efficiency (cd/A) of the red quantum dot light-emitting diodes prepared in Embodiments 4-6 is tested, and the test method is as follows: scanning from 0V to 7V at a step of 0.2 V, and respectively monitoring the current (A) and the brightness (nit/m²) by using the GIB source table and the integrating sphere to obtain the current efficiency test values.

The test results are shown in Table 2 below.

TABLE 2

| current efficiency (cd/A) | 1 day later | 3 days later | 6 days later |
|---|---|---|---|
| Embodiment 4 | 4.0 | 6.4 | 8.8 |
| Embodiment 5 | 4.7 | 5.9 | 7.8 |
| Embodiment 6 | 5.1 | 10.5 | 16.0 |

It can be seen from Table 2 that compared with the current efficiency of the first day, the current efficiency of the red quantum dot light emitting diode provided in Embodiment 4 is improved by 121% 6 days later; the current efficiency of the red quantum dot light emitting diode provided in Embodiment 5 is improved by 79.8% 6 days later; and the current efficiency of the red quantum dot light emitting diode provided in Embodiment 6 is improved by 213.6% 6 days later. It can be seen that the positive aging efficiency of the red quantum dot light emitting diodes provided by the embodiments of the present disclosure is significantly improved.

The above are merely preferred embodiments of the present disclosure and are not intended to limit the present disclosure. Any modification, equivalent replacement, improvement, etc. made within the spirit and principle of the present disclosure should be included within the protection scope of the present disclosure.

What is claimed is:

1. A quantum dot light emitting diode, comprising an anode and a cathode disposed opposite to each other, a quantum dot light-emitting layer disposed between the anode and the cathode, and an electronic functional layer disposed between the quantum dot light-emitting layer and the cathode;
wherein a surface of the cathode facing away from the anode is treated with an active material, or a buffer layer is provided on the surface of the cathode facing away from the anode, and material of the buffer layer contains an active material;
wherein the active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

2. The quantum dot light emitting diode according to claim 1, wherein the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.

3. The quantum dot light emitting diode according to claim 1, wherein in case where the cathode is a cathode whose surface facing away from the anode is treated with the active material, the active material on the surface of the cathode is 0.001%-1% of the total weight of the cathode.

4. The quantum dot light emitting diode according to claim 1, wherein in case where the buffer layer is provided on the surface of the cathode facing away from the anode, the material of the buffer layer is a mixed material of the active material and a polymer.

5. The quantum dot light emitting diode according to claim 4, wherein the polymer is selected from one or more of polymethyl methacrylate, polyvinyl chloride, poly α-methylstyrene resin, polybutylene terephthalate, polypropylene carbonate, polystyrene, polyhydroxyethyl methacrylate, ethyl polymethacrylate, ethyl polyacrylate, n-butyl polyacrylate, lauryl acrylate, and urethane acrylate.

6. The quantum dot light emitting diode according to any one of claims 1, 2, 4 and 5, wherein a weight percentage of the active ingredient in the buffer layer is 1%-70%.

7. The quantum dot light emitting diode according to any one of claims 1, 2, 4 and 5, wherein thickness of the buffer layer is 100 nm-20 μm.

8. The quantum dot light emitting diode according to any one of claims 1-3, wherein treatment with the active material comprises: cleaning the cathode with the active material solution; or
preparing a mixed solution containing the active material, depositing the mixed solution on the surface of the cathode; or
exposing the cathode to an atmosphere containing a gaseous active material.

9. The quantum dot light emitting diode according to any one of claims 1, 2, 4 and 5, wherein the buffer layer covers peripheral wall surfaces of the anode, the cathode, the quantum dot light-emitting layer, and the electronic functional layer.

10. A manufacturing method of quantum dot light emitting diode, comprising steps of:
providing a prefabricated device, which comprises an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer; and
cleaning the cathode with an active material solution, and preparing the quantum dot light emitting diode; wherein the active material in the active material solution is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

11. The manufacturing method of quantum dot light emitting diode according to claim 10, wherein a volume percentage content of the active material in the active material solution is 0.1%-100%.

12. The manufacturing method of quantum dot light emitting diode according to claim 11, wherein the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.

13. A manufacturing method of quantum dot light emitting diode, comprising steps of:
providing a prefabricated device, which comprises an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer; and
placing the prefabricated device in an atmosphere environment containing a gaseous active material, treating the cathode with the active material and preparing the quantum dot light emitting diode; wherein the gaseous active material is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

14. The manufacturing method of quantum dot light emitting diode according to claim 13, wherein the atmosphere environment is a mixed gaseous environment of the gaseous active material with at least one of gases such as oxygen, nitrogen, argon, and carbon dioxide.

15. The manufacturing method of quantum dot light emitting diode according to claim 14, wherein the gaseous active material is 1%-50% of total volume of the gases in the atmosphere environment.

16. The manufacturing method of quantum dot light emitting diode according to claim 14, wherein temperature of the gaseous environment is 25-150° C., and total pressure is −0.1-4 MPa.

17. The manufacturing method of quantum dot light emitting diode according to any one of claims 14-16, wherein the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.

18. A manufacturing method of quantum dot light emitting diode, comprising steps of:
providing a prefabricated device, which comprises an anode substrate, a quantum dot light-emitting layer coupled to an anode surface of the anode substrate, an electronic functional layer coupled to a surface of the quantum dot light-emitting layer facing away from the anode, and a cathode coupled to a surface of the electronic functional layer facing away from the quantum dot light-emitting layer; and
preparing a mixed solution containing an active material and a polymer, depositing the mixed solution on a surface of the cathode facing away from the anode, annealing, and preparing a buffer layer; wherein the active material in the active material solution is selected from at least one of an organic hydrocarbon having at least one hydrogen atom substituted with a carboxyl group, an organic ester containing a carbon-carbon double bond or a carbon-carbon triple bond or a benzene ring, and an unsaturated ketone.

19. The manufacturing method of quantum dot light emitting diode according to claim 18, wherein the active material is 1%-70% of total weight of the active material and the polymer in the mixed solution.

20. The manufacturing method of quantum dot light emitting diode according to claim 19, wherein the active material is selected from at least one of acrylic acid, benzoic acid, methacrylic acid, 3-butenoic acid, crotonic acid, acetic acid, propionic acid, butyric acid, isobutyric acid, hydroxyethyl methacrylate, methyl methacrylate, butyl acrylate, trimethylolpropane trienate, and N-vinyl pyrrolidone.
